(19) United States
(12) Patent Application Publication
(10) Pub. No.: US 2015/0206841 A1
(43) Pub. Date: Jul. 23, 2015

(54) SEMICONDUCTOR DEVICE AND MANUFACTURING METHOD THEREOF

(71) Applicant: KABUSHIKI KAISHA TOSHIBA, Minato-ku (JP)

(72) Inventors: Kazumasa ITO, Yokkaichi-Shi (JP); Kazuaki Nakajima, Tokyo (JP)

(73) Assignee: KABUSHIKI KAISHA TOSHIBA, Minato-ku (JP)

(21) Appl. No.: 14/200,797

(22) Filed: Mar. 7, 2014

Related U.S. Application Data
(60) Provisional application No. 61/928,451, filed on Jan. 17, 2014.

(51) Int. Cl. H01L 23/532; H01L 23/528; H01L 21/768

(52) U.S. Cl. CPC H01L 23/53238; H01L 21/76897; H01L 21/76802; H01L 21/76829; H01L 21/76879; H01L 21/7685; H01L 23/528

(57) ABSTRACT

A semiconductor device according to the present embodiment includes a first wiring made of copper. A metal film is provided on the first wiring and is made of cobalt, a cobalt alloy, nickel, or a nickel alloy. An interlayer dielectric film is provided on the first wiring or the metal film. Contact plugs are provided in the interlayer dielectric film, contact the metal film, and are made of tungsten or a carbon nanotube.

### CROSS REFERENCE TO RELATED APPLICATIONS

This application is based upon and claims the benefit of priority from the prior U.S. Provisional Patent Application No. 61/928,451, filed on Jan. 17, 2014, the entire contents of which are incorporated herein by reference.

### FIELD

The embodiments of the present invention relate to a semiconductor device and manufacturing method thereof.

### BACKGROUND

Conventionally, wirings made of copper and contact plugs made of aluminum are frequently used in a wiring structure of a semiconductor device. For example, an interlayer dielectric film is formed on a lower layer wiring made of copper and contact holes are formed in the interlayer dielectric film. Aluminum is then embedded in the contact holes by an aluminum reflow process. In this way, contact plugs made of aluminum are formed to contact the copper wiring.

In recent years, however, the diameter of the contact holes is reduced for downscaling of the semiconductor device. Furthermore, to decrease a parasitic capacitance between wiring layers, the interlayer dielectric film needs to be formed thick to some extent. In this case, the opening diameter of the contact holes reduces while the depth of the contact holes does not change so much. That is, the aspect ratio of the contact holes increases with downscaling of the semiconductor device. When the aspect ratio of the contact holes increases, aluminum cannot be embedded fully in the contact holes and voids may occur in the contact plugs. If voids occur in the contact plugs, an electrical connection between a lower layer wiring and an upper layer wiring may be cut.

### BRIEF DESCRIPTION OF THE DRAWINGS

FIG. 1 is a cross-sectional view showing an example of a configuration of a semiconductor device 100 according to a first embodiment;

FIGS. 2 to 6 are cross-sectional views showing a manufacturing method of the semiconductor device according to the first embodiment;

FIG. 7 is a cross-sectional view showing an example of a configuration of a semiconductor device 200 according to a second embodiment;

FIGS. 8 and 9 are cross-sectional views showing a manufacturing method of the semiconductor device according to the second embodiment;

FIG. 10 is a cross-sectional view showing an example of a configuration of a semiconductor device 300 according to a third embodiment;

FIGS. 11 to 13 are cross-sectional views showing a manufacturing method of the semiconductor device according to the third embodiment;

FIG. 14 is a cross-sectional view showing an example of a configuration of a semiconductor device 400 according to a fourth embodiment; and

FIGS. 15 to 17 are cross-sectional views showing a manufacturing method of the semiconductor device according to the fourth embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the present embodiment includes a first wiring made of copper. A metal film is provided on the first wiring and is made of cobalt, a cobalt alloy, nickel, or a nickel alloy. An interlayer dielectric film is provided on the first wiring or the metal film. Contact plugs are provided in the interlayer dielectric film, contact the metal film, and are made of tungsten or a carbon nanotube.

### First Embodiment

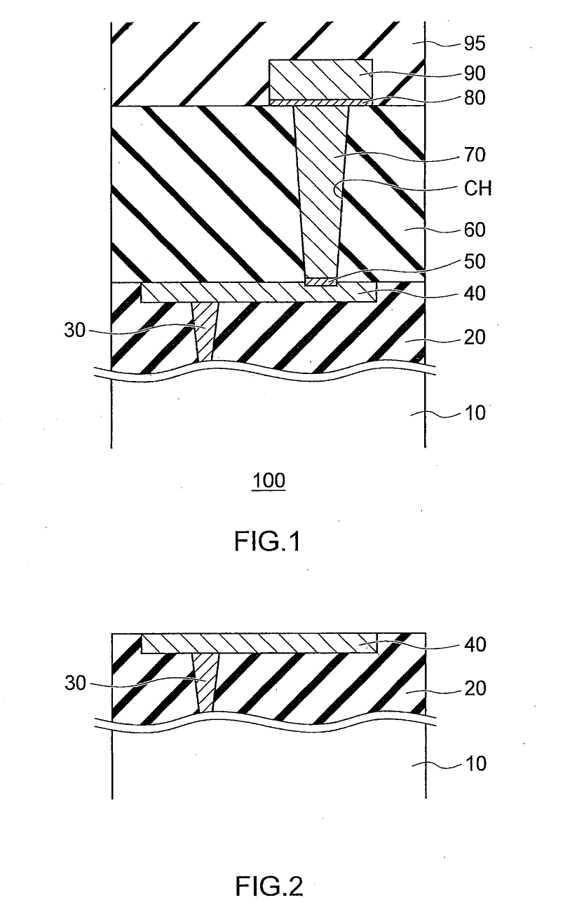

FIG. 1 is a cross-sectional view showing an example of a configuration of a semiconductor device 100 according to a first embodiment. It suffices that the semiconductor device 100 according to the first embodiment is a semiconductor device having a wiring structure and the semiconductor device 100 can be a memory, a system LSI (Large-Scale Integration), or the like.

The semiconductor device 100 includes a substrate 10, an interlayer dielectric film 20, contact plugs 30, a lower layer wiring 40, a metal film 50, an interlayer dielectric film 60, contact plugs 70, a barrier metal 80, an upper layer wiring 90, and an interlayer dielectric film 95.

The substrate 10 is a semiconductor substrate such as a silicon substrate. Semiconductor elements such as transistor, capacitors, and resistive elements (not shown) are formed on the substrate 10. The interlayer dielectric film 20 is provided above the substrate 10 to cover the semiconductor elements. The interlayer dielectric film 20 is formed using an insulating film such as a silicon dioxide film or silicon nitride film.

Each of the contact plugs 30 passes through the interlayer dielectric film 20 to electrically connect to any of the semiconductor elements. The contact plugs 30 are formed using a conductive metal such as copper, aluminum, or tungsten.

The lower layer wiring 40 serving as a first wiring is formed on the contact plugs 30 and the interlayer dielectric film 20. The lower layer wiring 40 is formed using, for example, copper.

The metal film 50 is formed on at least parts of the upper surface of the lower layer wiring 40. In the first embodiment, the metal film 50 is provided selectively between the bottom surfaces of the contact plugs 70 and the lower layer wiring 40. Accordingly, during embedment of a material of the contact plugs 70 in contact holes CH, the metal film 50 functions as a seed layer or a catalytic layer of the material of the contact plugs 70. The metal film 50 is formed using, for example, cobalt, a cobalt alloy, nickel, or a nickel alloy. The cobalt alloy serving as the metal film 50 can be, for example, CoW, CoWP, CoWB, CoMoP, CoMoB, or CoBP. The nickel alloy serving as the metal film 50 can be, for example, MW, NiWP, NiWB, NiMoP, NiMoB, or NiBP.

The interlayer dielectric film 60 is provided on the lower layer wiring 40 and the interlayer dielectric film 20. The interlayer dielectric film 60 is formed using an insulating film such as a silicon dioxide film or a silicon nitride film similarly to the interlayer dielectric film 20.

The contact plugs 70 are embedded in contact holes CH provided in the interlayer dielectric film 60. Upper ends of the contact plugs 70 contact the bottom surface of the upper layer wiring 90 or the barrier metal 80 and lower ends of the contact plugs 70 contact the upper surface of the metal film 50. That is, the contact plugs 70 extend from the upper layer wiring 90 or the barrier metal 80 and pass through the interlayer dielectric film 60 to reach the metal film 50. The contact plugs 70 thereby electrically connect between the upper layer wiring 90 and the lower layer wiring 40. The contact plugs 70 are formed using a conductive material such as tungsten or a carbon nanotube (hereinafter, also CNT). For example, when the contact plugs 70 are tungsten, the contact plugs 70 are grown in the contact holes CH by a selective CVD (Chemical Vapor Deposition) method or the like that uses the metal film 50 as a seed layer. A case where the contact plugs 70 are the CNT will be explained in a second embodiment.

The barrier metal 80 is formed on the contact plugs 70. The barrier metal 80 is provided to suppress diffusion of a material of the upper layer wiring 90 to the contact plugs 70 or to the interlayer dielectric film 60. The barrier metal 80 is formed using a metal such as titanium or a titanium nitride. When the material of the upper layer wiring 90 does not diffuse or when diffusion of the material of the upper layer wiring 90 causes no problem, the barrier metal 80 does not need to be formed and can be omitted.

The upper layer wiring 90 is provided above the contact plugs 70 or the interlayer dielectric film. 60 with the barrier metal 80 interposed therebetween. When the barrier metal 80 is not provided, the upper layer wiring 90 is provide on the contact plugs 70 or the interlayer dielectric film 60. The upper layer wiring 90 is formed using a conductive metal such as copper or aluminum.

The interlayer dielectric film 95 is formed to cover the upper layer wiring 90. The interlayer dielectric film 95 is formed using an insulating film such as a silicon dioxide film or a silicon nitride film.

As described above, in the first embodiment, the metal film 50 is provided between the contact plugs 70 and the lower layer wiring 40. That is, the metal film 50 is provided on the bottom surfaces of the contact holes CH. Meanwhile, the metal film 50 is not provided between the interlayer dielectric film 60 and the contact plugs 70.

Generally, a barrier metal (not shown) is sometimes provided on the entire inner surfaces of the contact holes CH. However, the metal film 50 according to the first embodiment is different from such a barrier metal and is not interposed between the interlayer dielectric film 60 and the contact plugs 70. Therefore, the metal film 50 does not have a function to suppress diffusion of the material of the contact plugs 70 to the interlayer dielectric film 60.

In the first embodiment, however, the metal film 50 is provided between the contact plugs 70 and the lower layer wiring 40. Accordingly, the metal film 50 can serve as a barrier metal and can suppress diffusion of the material of the contact plugs 70 to the lower layer wiring 40 or diffusion of the material of the lower layer wiring 40 to the contact plugs 70.

Furthermore, the metal film 50 functions as a seed layer for selective CVD during formation of the contact plugs 70. At that time, the material (tungsten, for example) of the contact plugs 70 is grown using the metal film 50 as a seed and is not grown on the surface of the interlayer dielectric film 60 (a silicon dioxide film, for example). Therefore, the material of the contact plugs 70 is gradually grown (deposited) from the bottom surfaces of the contact holes CH where the metal film 50 is provided to upper portions (opening portions) of the contact holes CH. The material of the contact plugs 70 is not grown from the inner side surfaces of the contact holes CH and the upper surface of the interlayer dielectric film 60, which are formed of the insulating film. Accordingly, the material of the contact plugs 70 is gradually grown from the bottom portions of the contact holes CH to the opening portions of the contact holes CH and can be filled in the contact holes CH in proper quantities. This prevents voids from occurring in the contact plugs 70. Because occurrence of voids can be suppressed, the contact plugs 70 can reliably provide an electrical connection between the upper layer wiring 90 and the lower layer wiring 40.

Furthermore, because the material of the contact plugs 70 is not deposited on the upper surface of the interlayer dielectric film 60, a polishing process by a CMP (Chemical Mechanical Polishing) method or the like is not required after formation of the contact plugs 70. Accordingly, the need of a polishing process or a planarizing process can be eliminated and wastes of the material of the contact plugs 70 can be reduced.

When tungsten is used as the material of the contact plugs 70, tungsten has a higher embeddability (coverage) than aluminum. Therefore, use of tungsten as the material of the contact plugs 70 can suppress occurrence of voids in the contact plugs 70 more effectively.

In a normal aluminum reflow process, as mentioned above, aluminum cannot be embedded fully in the contact holes and voids occur due to an increase in the aspect ratio of the contact holes.

On the other hand, according to the first embodiment, when tungsten is used as the material of the contact plugs 70, tungsten is selectively grown using the metal film 50 as a seed. Therefore, even when the aspect ratio of the contact holes CH increases, tungsten is gradually grown from the metal film 50 to the upper portions of the contact holes CH. Accordingly, tungsten is filled in the contact holes CH in proper quantities and occurrence of voids can be suppressed.

FIGS. 2 to 6 are cross-sectional views showing a manufacturing method of the semiconductor device according to the first embodiment. Semiconductor elements (not shown) are first formed on the substrate 10. The interlayer dielectric film 20 is then deposited above the substrate 10. The contact plugs 30 are then formed in the interlayer dielectric film 20. The lower layer wiring 40 is further embedded in a surface area of the interlayer dielectric film 20. The lower layer wiring 40 is formed, for example, by embedding copper in the interlayer dielectric film 20 using a damascene method. The lower wiring 40 is formed using a conductive metal such as copper. A structure shown in FIG. 2 is thereby obtained.

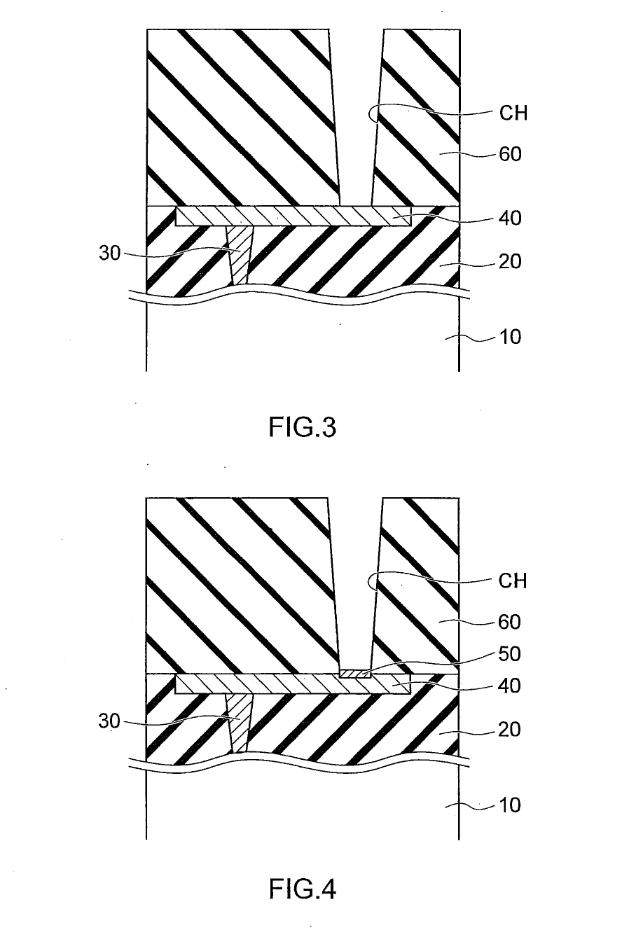

The interlayer dielectric film 60 is then deposited on the lower layer wiring 40 and the interlayer dielectric film 20 as shown in FIG. 3. The interlayer dielectric film 60 is formed using an insulating film such as a silicon dioxide film or a silicon nitride film.

The contact holes CH are then formed in the interlayer dielectric film 60 using a lithographic technique and an etching technique. In this way, the contact holes CH are formed to extend from the upper surface of the interlayer dielectric film 60 to reach the lower layer wiring 40 as shown in FIG. 3. The aspect ratio of the contact holes CH is relatively high due to downscaling of the semiconductor device and reduction in the parasitic capacitance between wiring layers.

The metal film 50 is then selectively formed on parts of the upper surface of the lower layer wiring 40 (copper) exposed at the bottom portions of the contact holes CH using an electroless plating method. At that time, as shown in FIG. 4, the metal film 50 is formed at the bottom portions of the contact holes CH (on the lower layer wiring 40) and is not formed on side wall surfaces of the contact holes CH (on the interlayer dielectric film 60). As mentioned above, the metal film 50 is formed using, for example, cobalt, a cobalt alloy, nickel, or a nickel alloy. The cobalt alloy can be any of CoW, CoWP, CoWB, CoMoP, CoMoB, and CoBP, for example. The nickel alloy can be any of NiW, NiWP, NiWB, NiMoP, NiMoB, and NiBP, for example.

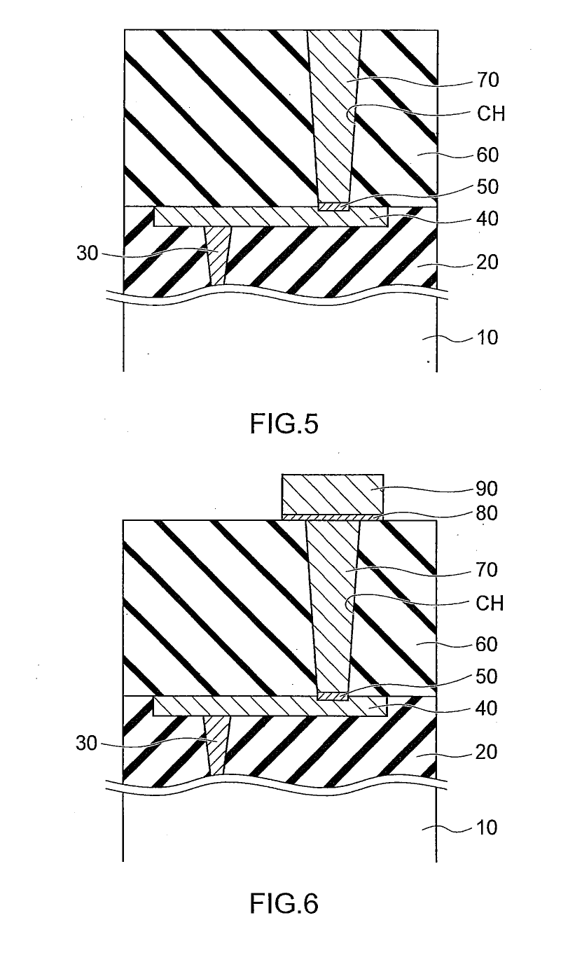

The material of the contact plugs 70 is then formed in the contact holes CH using the selective CVD method as shown in FIG. 5. When tungsten is used as the material of the contact plug 70, tungsten is formed on the metal film 50 by the selective CVD method using the metal film 50 as a seed. For example, tungsten is formed by reducing WF₆ gas with H₂. In this case, tungsten is selectively grown on the metal film 50 and is not grown on the interlayer dielectric film 60. That is, the material of the contact plugs 70 is grown or deposited on the bottom portions of the contact holes CH without grown from the side wall surfaces of the contact holes CH. Therefore, the material of the contact plugs 70 is gradually grown from the bottom portions of the contact holes CH toward the opening portions of the contact holes CH. This can suppress voids from occurring in the contact plugs 70. Furthermore, the material of the contact plugs 70 is not deposited on the upper surface of the interlayer dielectric film 60 either. Therefore, a polishing process or a planarizing process for removing unwanted parts of the material of the contact plugs 70 is not required. Accordingly, in the manufacturing method according to the first embodiment, wastes of the material of the contact plugs 70 can be reduced and the manufacturing process can be shortened.

Copper to be used for the lower layer wiring 40 reacts with WF₆ gas and H₂ gas to be used to grow tungsten. Therefore, copper is inappropriate for a seed of tungsten.

The material of the barrier metal 80 is then deposited on the contact plugs 70 and the material of the upper layer wiring 90 is deposited on the barrier metal 60. The barrier metal 80 and the upper layer wiring 90 are then processed using a lithographic technique and an etching technique. The barrier metal 80 and the upper layer wiring 90 are thereby formed on the contact plugs 70 as shown in FIG. 6.

An interlayer dielectric film, a wiring layer, and the like are then further formed, whereby the semiconductor device 100 shown in FIG. 1 is completed.

According to the first embodiment, the metal film 50 is formed selectively on the lower layer wiring 40 (copper) at the bottom portions of the contact holes CH by electroless plating. In this way, the metal film 50 is formed at the bottom portions of the contact holes CH without formed on the side wall surfaces of the contact holes CH and the upper surface of the interlayer dielectric film 60.

Generally, a cobalt alloy or a nickel alloy is used as a cap metal or a barrier metal in the semiconductor device. The cap metal is provided to improve an EM (Electro Migration) resistance (reliability) of a copper wiring. The barrier metal is used to suppress diffusion of oxygen in an oxide film to copper.

On the other hand, according to the first embodiment, the metal film 50 functions as a seed for the selective CVD during formation of the contact plugs 70. For example, tungsten as the material of the contact plugs 70 is grown selectively on the metal film 50 using the metal film 50 as a seed and is not grown on the surface of the interlayer dielectric film 60. Accordingly, the contact plugs 70 are filled in the contact holes CH without occurrence of voids. A polishing process or a planarizing process is not required after formation of the contact plugs 70 and wastes of the material of the contact plugs 70 can be reduced.

When tungsten is used as the material of the contact plugs 70, tungsten has a higher embeddability (coverage) than aluminum. Therefore, even when the aspect ratio of the contact holes CH increases, use of tungsten as the material of the contact plugs 70 can suppress occurrence of voids in the contact plugs 70 more effectively.

### Second Embodiment

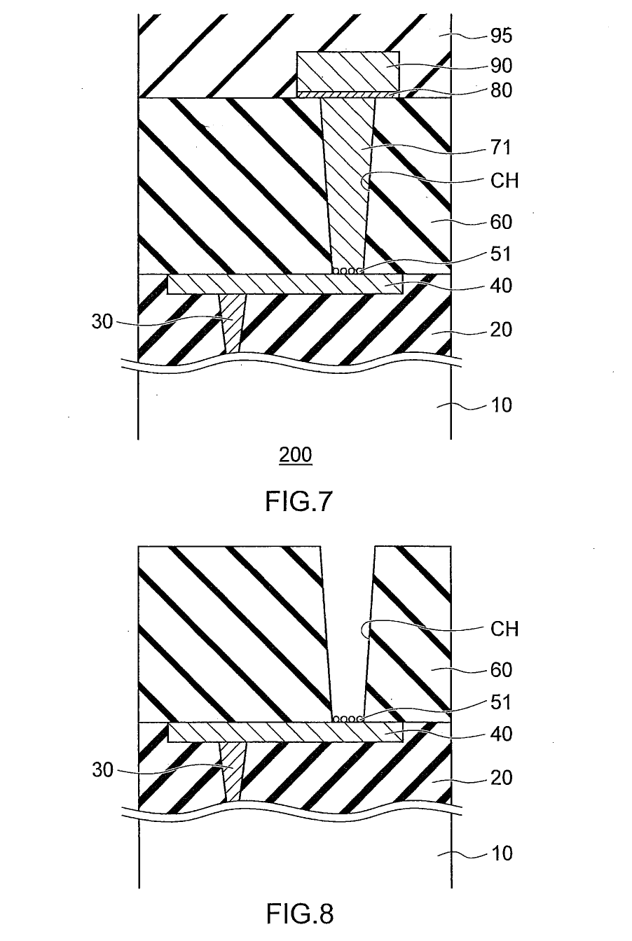

FIG. 7 is a cross-sectional view showing an example of a configuration of a semiconductor device 200 according to a second embodiment. In the second embodiment, metal particles 51 are adopted instead of the metal film 50. A material of the metal particles 51 can be the same as that of the metal film 50. Contact plugs 71 are formed using a carbon nanotube (CNT). Other configurations of the second embodiment can be identical to corresponding ones of the first embodiment.

When the contact plugs 71 are, for example, the CNT, the contact plugs 71 are grown in the contact holes CH by a plasma CVD method, a thermal CVD method, or the like using the metal particles 51 as a catalytic layer. To grow the CNT easily and rapidly, it is preferable that the metal particles 51 be formed not in a film or a layer but in granules as shown in FIG. 7. After formation of the contact plugs 71, the metal particles 51 are located at interfaces between the contact plugs 71 and the lower layer wiring 40. By using the granular metal particles 51 as a catalyst, the CNT can be grown easily and rapidly by the plasma CVD method or the thermal CVD method.

Furthermore, when the CNT is used as the material of the contact plugs 71, the CNT is selectively grown on the metal particles 51 using the metal particles 51 as a catalyst. Therefore, even when the aspect ratio of the contact holes CH increases, the CNT is gradually grown from the metal particles 51 to the upper portions of the contact holes CH. Accordingly, also when the CNT is used as the material of the contact plugs 71, the CNT can be filled in the contact holes CH in proper quantities. Therefore, the second embodiment can achieve effects identical to those of the first embodiment.

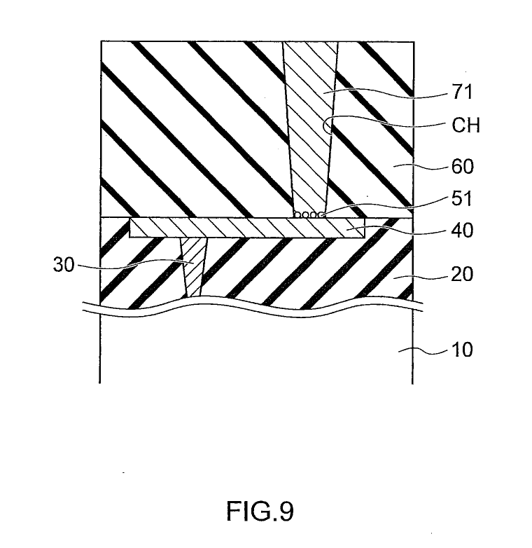

FIGS. 8 and 9 are cross-sectional views showing a manufacturing method of the semiconductor device according to the second embodiment. After processes explained with reference to FIGS. 2 and 3 are performed, the metal particles 51 are selectively formed by the electroless plating method on parts of the upper surface of the lower layer wiring 40 (copper) exposed at the bottom portions of the contact holes CH. At that time, the metal particles 51 are formed at the bottom portions of the contact holes CH (on the lower layer wiring 40) and are not formed on the side wall surfaces of the contact holes CH (on the interlayer dielectric film 60) as shown in FIG. 8. As mentioned above, the material of the metal particles 51 can be the same as that of the metal film 50.

The material of the contact plugs 71 is then formed in the contact holes CH using the plasma CVD method or the thermal CVD method as shown in FIG. 9. When the CNT is used as the material of the contact plugs 71, the CNT is formed on the metal particles 51 by the plasma CVD method or the thermal CVD method using the metal particles 51 as a catalyst. In this case, while the CNT is grown or deposited selectively on the metal particles 51, the CNT is not grown or deposited on the interlayer dielectric film 60. That is, the material of the contact plugs 71 is grown or deposited on the bottom portions of the contact holes CH without grown or deposited from the side wall surfaces of the contact holes CH. Therefore, the material of the contact plugs 71 is gradually grown or deposited from the bottom surfaces of the contact holes CH toward the opening portions of the contact holes CH. This can suppress occurrence of voids in the contact plugs 71. Because the material of the contact plugs 71 is not deposited on the upper surface of the interlayer dielectric film 60 either, a polishing process or a planarizing process for removing unwanted parts of the material of the contact plugs 71 is not required. With this configuration, the manufacturing method according to the second embodiment can achieve effects identical to those of the manufacturing method according to the first embodiment.

Carbon is hardly dissolved in copper to be used for the lower layer wiring 40. Therefore, copper is inappropriate for a catalyst of the CNT. Cobalt, a cobalt alloy, nickel, or a nickel alloy used as a catalyst (the metal particles 51) in the second embodiment is a material that can be easily electroless-plated on the lower wiring layer 40 (copper) and can relatively easily dissolve carbon.

Subsequently, processes explained with reference to FIG. 6 are performed, whereby the semiconductor device 200 shown in FIG. 7 is completed.

According to the second embodiment, the metal particles 51 are selectively formed on parts of the lower layer wiring 40 at the bottom portions of the contact holes CH using the electroless plating or the plasma CVD method. The metal particles 51 function as a catalyst for the plasma CVD method or the thermal CVD method during formation of the contact plugs 71. Therefore, the CNT as the material of the contact plugs 71 is selectively grown on the metal particles 51 using the metal particles 51 as a catalyst and is not grown on the surface of the interlayer dielectric film 60. Accordingly, the contact plugs 71 are filled in the contact holes CH without occurrence of voids. Furthermore, a polishing process or a planarizing process is not required after formation of the contact plugs 71 and wastes of the material of the contact plugs 71 can be reduced. Further, the second embodiment can also achieve the effects of the first embodiment.

### Third Embodiment

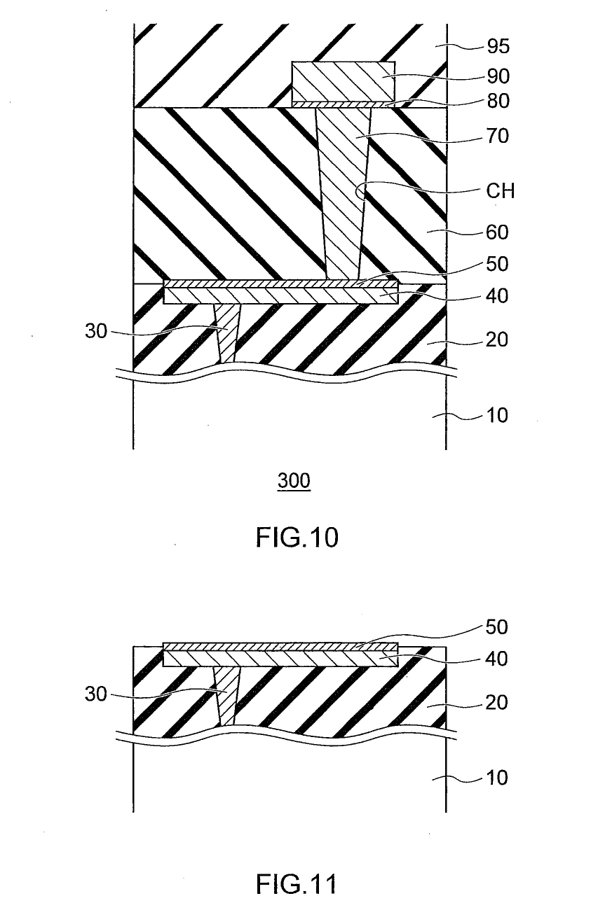

FIG. 10 is a cross-sectional view showing an example of a configuration of a semiconductor device 300 according to a third embodiment. In the third embodiment, the metal film 50 is formed on the entire upper surface of the lower layer wiring 40. Other configurations of the third embodiment can be identical to corresponding ones of the first embodiment.

The metal film 50 is provided on the entire upper surface of the lower layer wiring 40. However, during formation of the contact plugs 70, the interlayer dielectric film 60 covers the metal film 50 except for parts corresponding to the bottom portions of the contact holes CH. Therefore, the material of the contact plugs 70 is gradually grown from the bottom surfaces of the contact holes CH where the metal film 50 is provided to the upper portions (opening portions) of the contact holes CH. The material of the contact plugs 70 is not grown from the inner side surfaces of the contact holes CH and the upper surface of the interlayer dielectric film 60, which are made of the insulating film. Therefore, the third embodiment can achieve effects identical to those of the first embodiment.

The metal film 50 covers the entire upper surface of the lower layer wiring 40. Accordingly, in the third embodiment, diffusion of the material of the lower layer wiring 40 to the interlayer dielectric film 60 can be suppressed. Furthermore, diffusion of oxygen in the interlayer dielectric film 60 to the lower layer wiring 40 can be suppressed.

FIGS. 11 to 13 are cross-sectional views showing a manufacturing method of the semiconductor device according to the third embodiment. After the processes explained with reference to FIG. 2 are performed, the metal film 50 is formed on the upper surface of the lower layer wiring 40 using the electroless plating method as shown in FIG. 11. Because the electroless plating method is used, the metal film 50 is selectively deposited on the entire upper surface of the lower layer wiring 40 and is not deposited on the interlayer dielectric film 20.

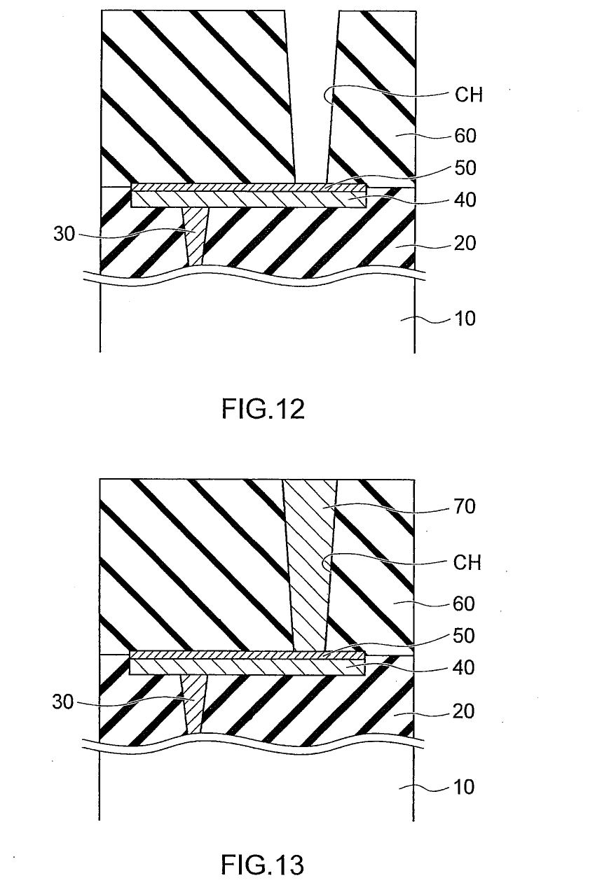

The interlayer dielectric film 60 is then deposited on the metal film 50 and the interlayer dielectric film 20 as shown in FIG. 12. The contact holes CH are then formed in the interlayer dielectric film 60 using a lithographic technique and an etching technique. These processes are as explained with reference to FIG. 3.

The material of the contact plugs 70 is formed in the contact holes CH using the selective CVD method as shown in FIG. 13. When tungsten is used as the material of the contact plugs 70, tungsten is formed on the metal film 50 by the selective CVD method using the metal film 50 as a seed as explained with reference to FIG. 5. At that time, the material of the contact plugs 70 is grown at the bottom portions of the contact holes CH and is not grown from the side wall surfaces of the contact holes CH. Therefore, the third embodiment has effects identical to those of the first embodiment.

The barrier metal 80 and the upper layer wiring 90 are then formed on the contact plugs 70. An interlayer dielectric film, a wiring layer, and the like are then further formed, whereby the semiconductor device 300 shown in FIG. 10 is completed.

The metal film 50 is provided on the entire upper surface of the lower layer wiring 40. However, during formation of the contact plugs 70, the interlayer dielectric film 60 covers the metal film 50 except for parts corresponding to the bottom portions of the contact holes CH. Therefore, the third embodiment can achieve effects identical to those of the first embodiment.

The metal film 50 covers the entire upper surface of the lower layer wiring 40. Accordingly, diffusion of the material of the lower layer wiring 40 to the interlayer dielectric film 60 can be suppressed. Furthermore, diffusion of oxygen in the interlayer dielectric film 60 to the lower layer wiring 40 can be suppressed.

### Fourth Embodiment

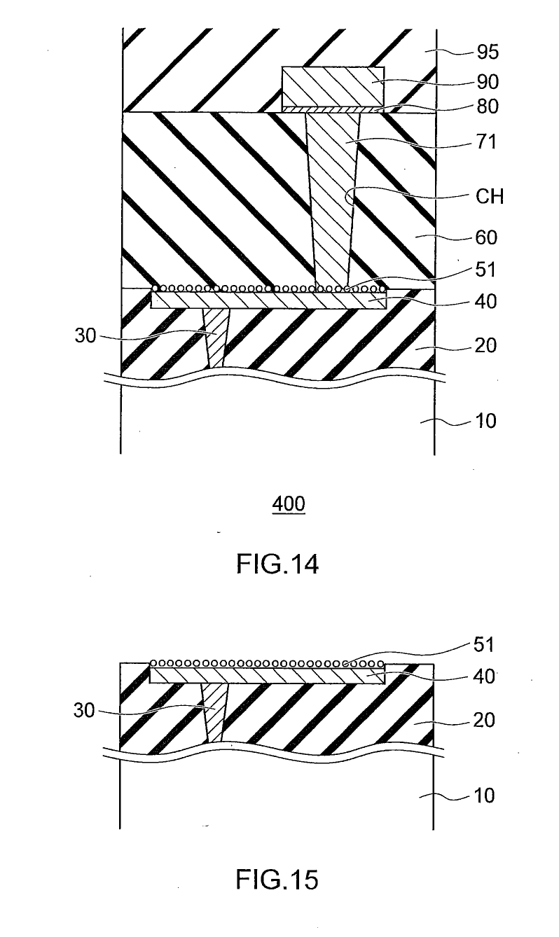

FIG. 14 is a cross-sectional view showing an example of a configuration of a semiconductor device 400 according to a fourth embodiment. In the fourth embodiment, the metal particles 51 are adopted instead of the metal film 50. A material of the metal particles 51 can be the same as that of the metal film 50. The contact plugs 71 are formed using a CNT. Other configurations of the fourth embodiment can be identical to corresponding ones of the third embodiment.

When the contact plugs 71 are, for example, the CNT, the contact plugs 71 are grown in the contact holes CH by the plasma CVD method, the thermal CVD method, or the like using the metal particles 51 as a catalytic layer. To grow the CNT easily and rapidly, it is preferable that the metal particles 51 be formed not in a film or a layer but in granules as shown in FIG. 14. After formation of the contact plugs 71, the metal particles 51 are located at interfaces between the contact plugs 71 and the lower layer wiring 40. Use of the metal particles 51 as a catalyst enables the CNT as the material of the contact plugs 71 to be grown easily and rapidly by the plasma CVD method or the thermal CVD method.

Furthermore, when the CNT is used as the material of the contact plugs 71, the CNT is selectively grown on the metal particles 51 using the metal particles 51 as a catalyst. Therefore, even when the aspect ratio of the contact holes CH increases, the CNT is gradually grown from the metal particles 51 to the upper portions of the contact holes CH. Accordingly, also when the CNT is used as the material of the contact plugs 71, the CNT can be filled in the contact holes CH in proper quantities. Accordingly, the fourth embodiment can achieve effects identical to those of the third embodiment.

FIGS. 15 to 17 are cross-sectional views showing a manufacturing method of the semiconductor device according to the fourth embodiment. After the processes explained with reference to FIG. 2 are performed, the metal particles 51 are formed on the upper surface of the lower layer wiring 40 using the electroless plating method as shown in FIG. 15. Because the electroless plating method is used, the metal particles 51 are selectively deposited on the entire upper surface of the lower layer wiring 40 without deposited on the interlayer dielectric film 20.

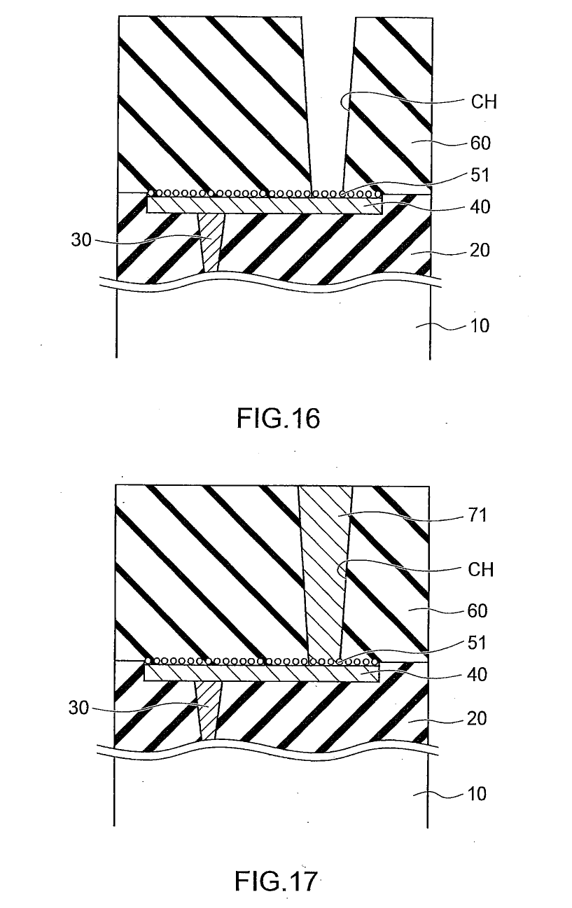

The interlayer dielectric film 60 is then deposited on the metal particles 51 and the interlayer dielectric film 20 as shown in FIG. 16. The contact holes CH are then formed in the interlayer dielectric film 60 using a lithographic technique and an etching technique. These processes are as explained with reference to FIG. 3.

The material of the contact plugs 71 is then formed in the contact holes CH using the selective CVD method as shown in FIG. 17. When the CNT is used as the material of the contact plugs 71, the CNT is formed on the metal particles 51 by the plasma CVD method or the thermal CVD method using the metal particles 51 as a seed. At that time, the material of the contact plugs 71 is deposited at the bottom portions of the contact holes CH and is not deposited on the side wall surfaces of the contact holes CH. Therefore, the fourth embodiment has effects identical to those of the second embodiment.

Subsequently, the processes explained with reference to FIG. 6 are performed, whereby the semiconductor device 400 shown in FIG. 14 is completed.

According to the fourth embodiment, the metal particles 51 are selectively formed on the entire upper surface of the lower layer wiring 40 at the bottom of the contact holes CH using the electroless plating method. The metal particles 51 function as a catalyst for the plasma CVD method or the thermal CVD method during formation of the contact plugs 71. Therefore, the CNT as the material of the contact plugs 71 is selectively grown on the metal particles 51 using the metal particles 51 as a catalyst and is not grown on the surface of the interlayer dielectric film 60. The metal particles 51 are provided on the entire upper surface of the lower layer wiring 40. However, during formation of the contact plugs 71, the interlayer dielectric film 60 covers the metal particles 51 except for parts corresponding to the bottom portions of the contact holes CH. Therefore, the fourth embodiment can achieve effects identical to those of the second embodiment.

The metal particles 51 cover the entire upper surface of the lower layer wiring 40. Accordingly, diffusion of the material of the lower layer wiring 40 to the interlayer dielectric film 60 can be suppressed. Furthermore, diffusion of oxygen in the interlayer dielectric film 60 to the lower layer wiring 40 can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first wiring made of copper;
a metal film on the first wiring, the metal film being made of cobalt, a cobalt alloy, nickel, or a nickel alloy;
an interlayer dielectric film on the first wiring or the metal film; and
contact plugs in the interlayer dielectric film, the contact plugs contacting the metal film and being made of tungsten or a carbon nanotube.

2. The device of claim 1, wherein the metal film is located selectively between bottom surfaces of the contact plugs and the first wiring.

3. The device of claim 1, wherein the metal film is located on an entire upper surface of the first wiring.

4. The device of claim 1, further comprising a second wiring above the contact plugs and the interlayer dielectric film.

5. The device of claim 4, wherein
the contact plugs pass through the interlayer dielectric film,
lower ends of the contact plugs contact an upper surface of the metal film, and
upper ends of the contact plugs contact a bottom surface of the second wiring.

6. The device of claim 1, wherein the metal film is made of any of CoW, CoWP, CoWB, CoMoP, CoMoB, CoBP, NiW, NiWP, NiWB, NiMoP, NiMoB, and NiBP.

7. A semiconductor device comprising:
a first wiring made of copper;
metal particles on the first wiring, the metal particles being made of cobalt, a cobalt alloy, nickel, or a nickel alloy;
an interlayer dielectric film on the first wiring or the metal particles; and
contact plugs in the interlayer dielectric film, the contact plugs contacting the metal particles and being made of tungsten or a carbon nanotube.

8. A manufacturing method of a semiconductor device, the method comprising:
forming a first wiring made of copper above a substrate;
forming an interlayer dielectric film on the first wiring;
forming contact holes in the interlayer dielectric film to reach the first wiring;
forming a metal film or metal particles made of cobalt, a cobalt alloy, nickel, or a nickel alloy on parts of the first wiring corresponding to bottom portions of the contact holes; and
forming contact plugs made of tungsten or a carbon nanotube in the contact holes to contact the metal film or the metal particles.

9. The method of claim 8, wherein the metal film or the metal particles are formed on the first wiring using an electroless plating method.

10. The method of claim 8, wherein the contact plugs are formed by being grown or deposited selectively on the metal film or the metal particles.

11. The method of claim 10, wherein the contact plugs are formed by a plasma CVD method or a thermal CVD method using the metal film or the metal particles as a seed or a catalyst.

12. The method of claim 8, further comprising forming a second wiring on the contact plugs and the interlayer dielectric film.

13. The method of claim 8, wherein the metal film or the metal particles are any of CoW, CoWP, CoWB, CoMoP, CoMoB, CoBP, NiW, NiWP, NiWB, NiMoP, NiMoB, and NiBP.

14. A manufacturing method of a semiconductor device, the method comprising:
forming a first wiring made of copper above a substrate;
forming a metal film or metal particles made of cobalt, a cobalt alloy, nickel, or a nickel alloy on the first wiring;
forming an interlayer dielectric film on the metal film or the metal particles;
forming contact holes in the interlayer dielectric film to reach the metal film or the metal particles on the first wiring; and
forming contact plugs made of tungsten or a carbon nanotube in the contact holes to contact the metal film or the metal particles.

15. The method of claim 14, wherein the metal film or the metal particles are formed on the first wiring using an electroless plating method.

16. The method of claim 14, wherein the contact plugs are formed by being grown or deposited selectively on the metal film or the metal particles.

17. The method of claim 16, wherein the contact plugs are formed by a plasma CVD method or a thermal CVD method using the metal film or the metal particles as a seed or a catalyst.

18. The method of claim 14, further comprising forming a second wiring on the contact plugs and the interlayer dielectric film.

19. The method of claim 14, wherein the metal film or the metal particles are any of CoW, CoWP, CoWB, CoMoP, CoMoB, CoBP, NiW, NiWP, NiWB, NiMoP, NiMoB, and NiBP.
